(19) United States
(12) Patent Application Publication
(10) Pub. No.: US 2026/0291162 A1
(43) Pub. Date: Sep. 24, 2026

(54) Method for Operating a Rotating Laser and Rotating Laser

(71) Applicant: Robert Bosch GmbH, Stuttgart (DE)

(72) Inventors: Tobias Zibold, Stuttgart (DE); Ben William Carabelli, Leinfelden-Echterdingen (DE); Markus Hahl, Korntal-Muenchingen (DE)

(21) Appl. No.: 19/567,741

(22) Filed: Mar. 16, 2026

(30) Foreign Application Priority Data
Mar. 20, 2025 (DE) 10 2025 110 735.1

(51) Int. Cl. H01S 3/101; H01S 3/02; H02P 6/08; H02P 21/18

(52) U.S. Cl. CPC H01S 3/101; H01S 3/025; H02P 6/08; H02P 21/18

(57) ABSTRACT

A method is disclosed for operating a rotating laser, which is operable in at least a first operating mode or a second operating mode and includes a housing in which, for rotation of a laser beam, a drive unit having a stator and a rotor for rotationally driving a spindle is arranged. A control and regulation unit for actuating the drive unit is assigned to the drive unit. The method includes (i) in response to a selection of the first operating mode, actuating the drive unit by the control and regulation unit with a first actuation mode assigned to the first operating mode, to which a brushless direct-current motor logic is assigned, (ii) in response to a selection of the second operating mode, actuating the drive unit by the control and regulation unit with a second actuation mode assigned to the second operating mode, to which a stepper motor logic is assigned, and (iii) driving the drive unit in the first actuation mode, or driving the drive unit in the second actuation mode.

This application claims priority under 35 U.S.C. § 119 to patent application no. DE 10 2025 110 735.1, filed on Mar. 20, 2025 in Germany, the disclosure of which is incorporated herein by reference in its entirety.

### BACKGROUND

The present disclosure relates to a method for operating a rotating laser, which is operable at least in a first operating mode or a second operating mode and comprises a housing in which, for rotation of a laser beam, a drive unit having a stator and a rotor for rotatably driving a spindle is arranged, wherein the drive unit is assigned to a control and regulation unit for actuating the drive unit.

From the prior art, such a method for operating a rotating laser is known, in which the rotating laser is operable in a first or second operating mode. For this purpose, the rotating laser comprises a housing, in which, for rotation of a laser beam, a drive unit having a stator and a rotor for rotatably driving a spindle is arranged. A control and regulation unit for actuating the drive unit is assigned to the drive unit. In response to a selection of the first operating mode, the control and regulation unit actuates the drive unit with an actuation mode assigned to the first operating mode. In response to a selection of the second operating mode, the control and regulation unit actuates the drive unit with the actuation mode assigned to the first operating mode, and a mechanical holding torque is applied to the drive unit to bring about of the second operating mode.

### SUMMARY

The disclosure relates to a method for operating a rotating laser that is operable at least in a first operating mode or a second operating mode and comprises a housing, in which, for rotation of a laser beam, a drive unit having a stator and a rotor for rotatably driving a spindle is arranged, wherein a control and regulation unit for actuating the drive unit is assigned to the drive unit. The method has the following steps:
in response to a selection of the first operating mode, actuating the drive unit by the control and regulating unit with a first actuation mode assigned to the first operating mode, to which a brushless direct-current motor logic is assigned,
in response to a selection of the second operating mode, actuating the drive unit by the control and regulating unit with a second drive-control mode assigned to the second operating mode, to which a stepper-motor logic is assigned, and
driving the drive unit in the first actuation mode, or driving the drive unit in the second actuation mode, wherein the drive unit is drivable in each case with a plurality of drive voltages which are assigned to the selected operating mode and are determined as a function of a current angular position of the spindle.
   The disclosure thus enables provision of a method for operating a rotating laser, wherein operation in a first or a second operating mode may be enabled by provision of a first actuation mode and a second actuation mode.

Preferably, in the first actuation mode, for generating a rotation, the control and regulation unit actuates the drive unit such that a magnetic field of the stator leads a magnetic field of the rotor by 90° in a predefined direction of rotation, and such that the amplitude of the magnetic field of the rotor is regulated as a function of a rate of change of the current angular position such that the drive unit rotates at a predefined rotational speed.

Thus, a suitable first actuation mode may be provided in a simple manner.

Preferably, in the second actuation mode, after determining the current angular position of the spindle, a query is performed as to whether the current angular position corresponds to a predefined angular position.

Thus, verification of a current angular position may be enabled easily and conveniently.

Preferably, the control and regulation unit actuates the drive unit for setting the predefined angular position of the spindle if the current angular position does not correspond to the predefined angular position.

Thus, setting of the predefined angular position may be enabled simply and reliably.

Preferably, in the second actuation mode, the control and regulation unit generates an electromagnetic holding torque for bringing about a standstill of the spindle in the predefined angular position.

Thus, a suitable second actuation mode may be provided in a simple manner.

Preferably, a magnetic field assigned to the stator generates the electromagnetic holding torque.

Thus, the electromagnetic holding torque may be generated easily and conveniently.

Preferably, in the second actuation mode, the control and regulation unit actuates the drive unit such that complex movement patterns of the spindle and/or an oscillating movement in a predefined angular range occur.

Thus, application-specific movements of the spindle may be enabled simply and reliably in the second actuation mode.

Furthermore, the present disclosure relates to a rotating laser having a housing, which is operable in at least a first operating mode or a second operating mode, wherein, in the housing, for rotation of a laser beam, a drive unit having a stator and a rotor for rotatably driving a spindle is arranged, wherein a control and regulation unit for actuating the drive unit is assigned to the drive unit. In the first operating mode, the control and regulation unit actuates the drive unit with a first actuation mode assigned to the first operating mode, to which a brushless direct-current motor logic is assigned, and, in the second operating mode, the control and regulation unit actuates the drive unit with a second actuation mode assigned to the second operating mode, to which a stepper-motor logic is assigned.

The disclosure thus enables the provision of a rotating laser, in which operation in a first or second operating mode may be enabled by providing a first actuation mode and a second actuation mode.

Preferably, the drive unit is drivable in each case with a plurality of drive voltages which are assigned to the selected operating mode and are determinable as a function of a current angular position of the spindle.

Thus, operation of the rotating laser in the selected operating mode may be enabled easily and conveniently.

Preferably, the rotor generates a first magnetic field and the stator generates a second magnetic field, wherein an alignment of the first magnetic field and the second magnetic field is achieved by driving the drive unit with the plurality of drive voltages assigned to the respective operating mode.

Thus, the first and second operating modes, or the first and second actuation modes, may be provided in a simple manner.

Preferably, the rotor comprises a toothed disk rotatable with the spindle and having an interior receptacle, wherein a magnetic disk for generating the first magnetic field is arranged in the interior receptacle.

Thus, the first magnetic field may be generated simply and reliably.

Preferably, the stator comprises a rotationally fixed printed circuit board having at least two coils facing the magnetic disk for generating the second magnetic field.

Thus, the second magnetic field may be generated easily and reliably.

Preferably, an angle sensor for detection of the current angular position of the spindle is assigned to the printed circuit board.

Thus, a determination of the current angular position of the spindle may be enabled in a simple manner.

Preferably, the angle sensor is configured to be a photoelectric barrier.

Thus, a suitable angle sensor may be provided simply and conveniently.

### BRIEF DESCRIPTION OF THE DRAWINGS

The disclosure is explained in greater detail in the following description on the basis of exemplary embodiments illustrated in the drawings. It shows:

FIG. 1 a perspective view of a rotating laser according to the disclosure having a drive unit,

FIG. 2 a perspective view of the drive unit with the spindle and the determination unit of the rotating laser of FIG. 1,

FIG. 3 a plan view of a printed circuit board assigned to the drive unit of FIG. 1 and FIG. 2,

FIG. 4 a perspective view of the spindle having the determination unit of FIG. 1 and FIG. 2, and

FIG. 5 a flow diagram of a method for operating the drive unit of FIG. 1 and FIG. 2.

### DETAILED DESCRIPTION

In the figures, elements having the same or comparable function are provided with identical reference signs and are described in greater detail only once.

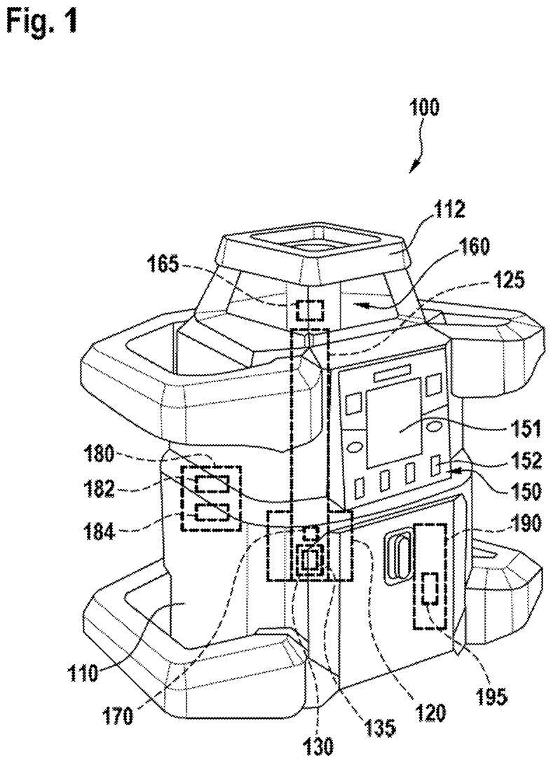

FIG. 1 shows an exemplary rotating laser 100 having a housing 110, in which a laser unit 130 having a laser diode 135 for generating a laser beam is arranged. In the context of the present disclosure, a “rotating laser” may also be understood to mean a construction laser or a leveling laser. Furthermore, a drive unit 120 for rotatably driving a spindle 125 is exemplarily arranged in the housing 110.

The laser unit 130 is arranged on the spindle 125 such that, by a rotation of the spindle 125, the laser beam generated by the laser unit 130 rotates in an assigned plane. For this purpose, a rotating head 160 having a beam deflector 165 is preferably assigned to the spindle 125. The beam deflector 165 is preferably configured to deflect the laser beam, whereby the laser beam defines the assigned plane. Depending on the configuration of the rotary laser 100, the projected plane may extend horizontally, vertically, or, for example, with a defined inclination angle relative to the ground surface. Preferably, the drive unit 120 is configured to be an electric motor.

Furthermore, an electronics unit 190 having a control and monitoring device 195 is preferably arranged in the housing 110. The control and monitoring device 195 is preferably configured to regulate laser power of the laser unit 130 as a function of an operating mode. Here, a rotational speed of the spindle 125 of the drive unit 120 is controlled or regulated. Preferably, a determination unit 170 is assigned to the spindle 125 for this purpose.

According to an exemplary embodiment, a protective cage 112 assigned to the rotating head 160 is assigned to the housing 110 for protection against an impact of the rotating head 160.

The electronics unit 190 is preferably assigned to an operating unit 150 having a display 151 and an input unit 152. The operating unit 150 is preferably connected to the electronics unit 190, in particular, to the control and monitoring device 195, in terms of control engineering or regulation engineering. The input unit 152 preferably comprises at least one keypad. Alternatively, the input unit 152 comprises a rotating controller, a touchscreen, a slider, a remote control, or the like. Via the input unit 152, a rotational speed for the spindle 125 may be input, for example, by a user. Alternatively, the rotational speed of the laser unit 130 is automatically controllable in one operating mode.

Preferably, the rotating laser 100 comprises a leveling unit 180. The leveling unit 180 preferably comprises at least one inclination sensor 184, which is configured to determine an inclination of the rotating head 160, in particular, of the beam deflector 165, and/or of the laser unit 130 relative to a predefined direction, preferably a horizontal direction, or relative to the vertical. Furthermore, the leveling unit 180 preferably comprises at least one inclination adjustment motor 182, which is configured to align the rotating head 160, in particular, the beam deflector 165, and/or the laser unit 130 relative to the vertical as a function of a position determined by way of the at least one inclination sensor 184, preferably an inclination of the laser unit 130 and/or of the rotating head 160.

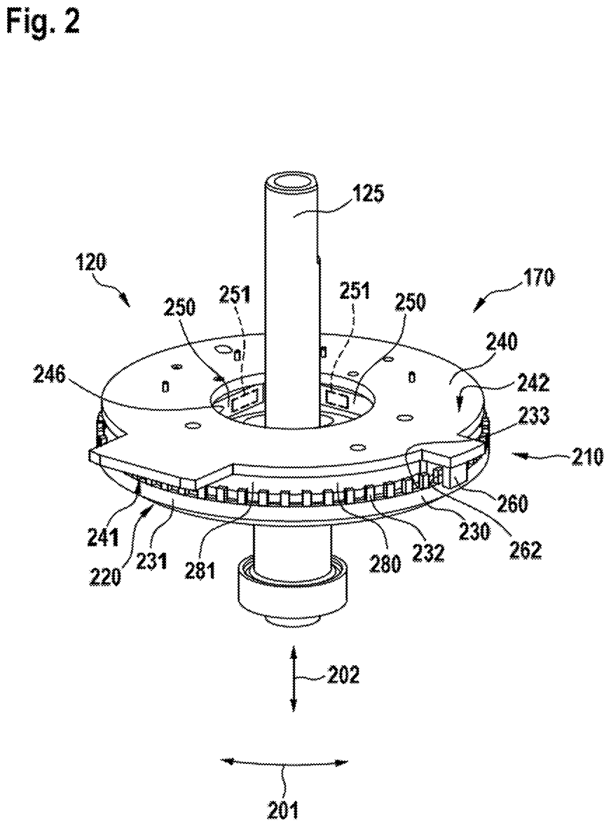

FIG. 2 shows the drive unit 120 having the spindle 125, and the determination unit 170 of the rotating laser 100 of FIG. 1. The drive unit 120 preferably comprises a stator 210 and a rotor 220 for rotatably driving the spindle 125. Preferably, the drive unit 120 is configured to be a spindle motor. Here, the drive unit 120 is preferably configured to be a brushless direct-current motor. Exemplarily, a magnetic disk 280 is assigned to the rotor 220, and at least two coils 251 are assigned to the stator 210. By energizing the coils 251, the spindle 125 may preferably be set into rotation in one operating mode.

Preferably, the determination unit 170 is assigned to the spindle 125. By way of example, the determination unit 170 comprises a toothed disk 230 and a photoelectric barrier 260. The toothed disk 230 preferably forms a functional unit with the photoelectric barrier 260, wherein the toothed disk 230 substantially generates a pulse sequence in the photoelectric barrier 260 for determining the angular position.

Preferably, the toothed disk 230 is connected to the spindle 125 in a rotationally fixed manner. According to one embodiment, the toothed disk 230 is configured in one piece with the spindle 125. The toothed disk 230 comprises a base body 231. Preferably, the base body 231 is configured in a shell-shaped manner having a receptacle 233. The receptacle 233 is preferably configured to at least partially receive the magnetic disk 280. Preferably, the toothed disk 230 comprises teeth 232 arranged distributed in the circumferential direction 201. The teeth 232 are formed on an outer circumference of the toothed disk 230 along a longitudinal extent 202 of the spindle 125.

The photoelectric barrier 260 is preferably provided for determining a relative change of a respective current angular position of the spindle 125 in the circumferential direction 201. The photoelectric barrier 260 is preferably configured to be a quadrature encoder. Such a quadrature encoder preferably comprises two photoelectric barriers which are preferably arranged with an offset relative to one another in the circumferential direction 201. A common light source is preferably assigned to the preferably two photoelectric barriers 260. Furthermore, two preferably separate photodiodes or phototransistors are assigned to the preferably two photoelectric barriers 260.

The photoelectric barrier 260 comprises a bottom surface and a preferably U-shaped receptacle 262. In the U-shaped receptacle 262, the teeth 232 of the toothed disk 230 are preferably received at least in sections. The bottom surface of the photoelectric barrier 260 is arranged on an underside 241 of a printed circuit board 240 facing the toothed disk 230.

The printed circuit board 240 is preferably arranged in the housing 110 of the rotating laser 100 of FIG. 1. Here, the printed circuit board 240 is preferably arranged parallel to the toothed disk 230. Exemplarily, the printed circuit board 240 comprises an inner recess 246 for coaxial arrangement on the spindle 125. The printed circuit board 240 comprises an upper side 242 arranged facing the beam deflector 165 of FIG. 1, and an underside 241 arranged facing the toothed disk 230. Preferably, the printed circuit board 240 comprises the at least two coils 251. The coils 251 are arranged on the underside 241 of the printed circuit board 240 facing the toothed disk 230. Preferably, the coils 251 are arranged on the printed circuit board 240 by way of coil holders 250. Preferably, the coil holders 250 are fixed on the printed circuit board 240.

The magnetic disk 280 preferably comprises a base body 281 that is at least in sections ring-shaped. Alternatively, the magnetic disk 280 may comprise at least two magnetic parts. Preferably, the magnetic disk 280 is configured to be a permanent magnet having N pole pairs.

Preferably, the determination unit 170 comprises a reference mark as an absolute reference. The reference mark is preferably assigned to the toothed disk 230. The reference mark may be configured, for example, as a reference tooth or a reference recess. Here, the teeth 232 of the toothed disk 230 have a first width, and the reference tooth or the reference recess has a second width. The second width is preferably greater than the first width.

Alternatively, the reference mark is configured to be a positioning feature on the magnetic disk 280 and is operatively connected to an absolute encoder. Here, the mechanically defined alignment of the beam deflector 165 of FIG. 1, the magnetic disk 280, and the toothed disk 230 relative to one another is not required. An absolute positioning is preferably achieved by way of an additional component, for example, a reflective light sensor, herein by way of example in the form of an absolute encoder on the printed circuit board 240, and a positioning feature on the magnetic disk 280. The positioning feature is preferably a reflective or light-absorbing sticker.

The positioning feature is preferably configured to identify one of the pole pairs of the magnetic disk 280. If the magnetic disk 280 comprises N pole pairs, the positioning feature must permit identification of an angular range having a width smaller than 360°/N. Preferably, the positioning feature has a width of 180°/N in the circumferential direction 201 of the spindle 125. Within each identified pole pair, an exact position determination is carried out via the (electrical) angle of a magnetic field generated by the coils 251. The determination of this angle is preferably carried out in the manufacturing process by arbitrary angular positioning of the spindle 125 by way of the coil field within the positioning feature.

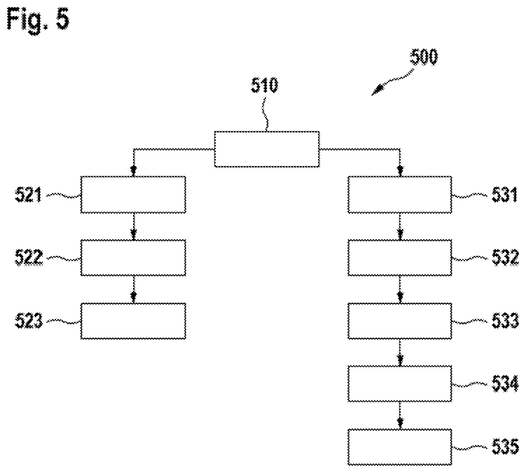

The rotating laser 100 is operable in at least a first operating mode and/or a second operating mode, wherein preferably only one of the operating modes is active in each case. In the first operating mode, the control and regulation unit 195 preferably actuates the drive unit 120 with a first actuation mode assigned to the first operating mode, to which a brushless direct-current motor logic (521 in FIG. 5) is assigned. In the second operating mode, the control and regulation unit 195 preferably actuates the drive unit 120 with a second actuation mode assigned to the second operating mode, to which a stepper-motor logic (531 in FIG. 5) is assigned.

The drive unit 120 is preferably drivable in each case with a plurality of drive voltages (523, 534 in FIG. 5) which are assigned to the selected operating mode. The plurality of drive voltages (523, 534 in FIG. 5) is determinable as a function of a current angular position (522, 532 in FIG. 5) of the spindle 125.

Preferably, the rotor 220 generates a first magnetic field, and the stator 210 generates a second magnetic field. An alignment of the first magnetic field and the second magnetic field is preferably achieved by driving the drive unit 120 with the plurality of drive voltages (523, 534 in FIG. 5) assigned to the respective operating mode. Here, as described above, the rotor 220 comprises the toothed disk 230 rotatable with the spindle 125, wherein the magnetic disk 280 for generating the first magnetic field is arranged in the interior receptacle 233 of the toothed disk 230. Furthermore, the stator 210 comprises the rotationally fixed printed circuit board 240 having the at least two coils 251 facing the magnetic disk 280 for generating the second magnetic field.

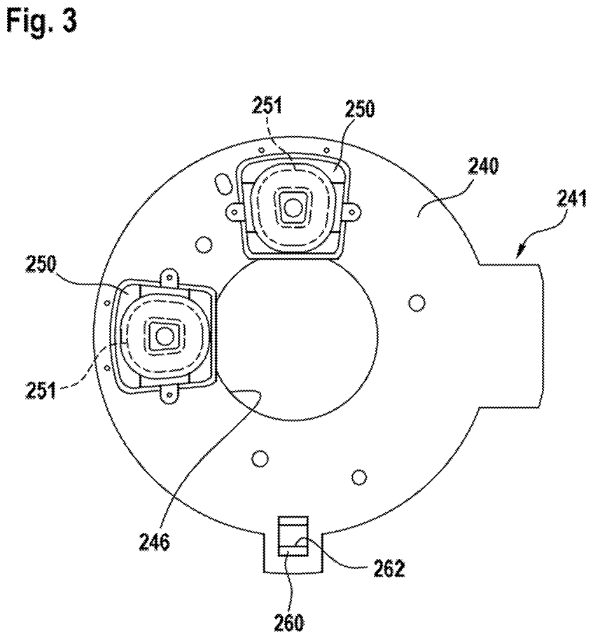

FIG. 3 shows the printed circuit board 240 of FIG. 2 as viewed from its underside 241. As described above, preferably two coils 251 are arranged on the underside 241 of the printed circuit board 240 by way of a coil holder 250. Furthermore, the photoelectric barrier 260 is preferably arranged on the underside 241 of the printed circuit board 240. The two coils 251 are arranged offset relative to one another by 90°. Preferably, the photoelectric barrier 260 is arranged opposite, or offset by 180°, relative to one of the two coils 251.

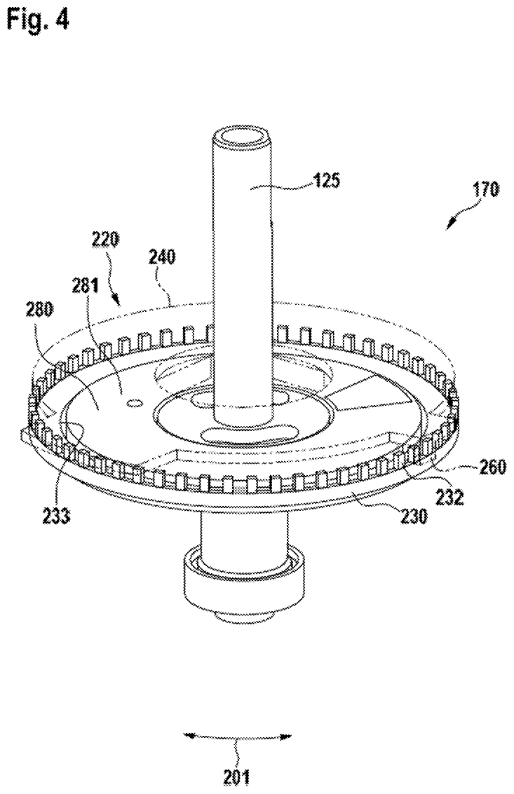

FIG. 4 shows the rotor 220 having the toothed disk 230, the magnetic disk 280, and the printed circuit board 240 of FIG. 2, which is illustrated transparently for improved clarity. The toothed disk 230 comprises the teeth 232 arranged distributed in the circumferential direction 201.

FIG. 5 shows an exemplary method 500 for operating the rotating laser 100 of FIG. 1, or the drive unit 120 of FIG. 1 and FIG. 2. In the method 500, an operating mode query 510 is first performed, that is to say whether the first or the second operating mode has been activated. Such an activation of the operating mode is preferably carried out via the operating unit 150 having the input unit 152 of the rotating laser 100 of FIG. 1 by a user of the rotating laser 100 of FIG. 1.

In response to a selection of the first operating mode, the drive unit 120 of FIG. 1 and FIG. 2 is actuated by the control and regulation unit 195 of FIG. 1 with the first actuation mode assigned to the first operating mode, to which a brushless direct-current motor logic 521 is assigned. Here, the drive unit 120 of FIG. 1 and FIG. 2, configured to be a brushless direct-current motor, is driven in rotation. The first operating mode is preferably a rotation mode of the rotating laser 100 of FIG. 1. Preferably, the drive unit 120 of FIG. 1 and FIG. 2 is excited by sinusoidal commutation, in which the coils 251 of FIG. 2 and FIG. 3 are actuated according to the sine of the relative angle between the coils 251 of FIG. 2 and FIG. 3 and the magnetic field of the rotor 220 of FIG. 2 and FIG. 4. Preferably, the drive unit 120 of FIG. 1 and FIG. 2 is driven at a constant speed.

In response to a selection of the second operating mode, the drive unit 120 of FIG. 1 and FIG. 2 is actuated by the control and regulation unit 195 of FIG. 1 with a second actuation mode assigned to the second operating mode, to which a stepper-motor logic 531 is assigned. Preferably, the second operating mode is a point mode, in which the spindle 125 of FIG. 1, FIG. 2, and FIG. 4 is arranged at a predefined angular position or within a predefined angular range. The drive unit 120 of FIG. 1 and FIG. 2 is subsequently driven in the selected actuation mode, wherein the drive unit 120 of FIG. 1 and FIG. 2 is driven in each case with a plurality of drive voltages 523, 534 which are assigned to the selected operating mode and are determined as a function of a current angular position 522, 532 of the spindle 125 of FIG. 1, FIG. 2, and FIG. 4.

Thus, in the first operating mode, or in the first actuation mode, the brushless direct-current motor logic 521 is activated, subsequently the current angular position 522 of the spindle 125 of FIG. 1, FIG. 2, and FIG. 4 is determined, and, as a function of the current angular position 522, the drive voltage 523 is determined and set.

Preferably, in the first actuation mode, the control and regulation unit 195 of FIG. 1 is actuated for generating a rotation of the drive unit 120 of FIG. 1 and FIG. 2, or of the spindle 125 of FIG. 1, FIG. 2, and FIG. 4, such that a magnetic field of the stator 210 of FIG. 2 leads a magnetic field of the rotor 220 of FIG. 2 and FIG. 4 by 90°in a predefined direction of rotation. Furthermore, the amplitude of the magnetic field of the rotor 220 of FIG. 2 and FIG. 4 is regulated as a function of a rate of change of the current angular position 522 such that the drive unit 120 of FIG. 1 and FIG. 2, or the spindle 125 of FIG. 1, FIG. 2, and FIG. 4, rotates at a predefined rotational speed.

In the second operating mode, or in the second actuation mode, the stepper-motor logic 531 is activated, and subsequently the current angular position 532 of the spindle 125 of FIG. 1, FIG. 2, and FIG. 4 is determined. Thereafter, a query 533 is performed as to whether the current angular position 532 corresponds to a predefined angular position. If the current angular position 532 does not correspond to the predefined angular position, then the selected or predefined angular position is set. Subsequently, the drive voltage 534 is determined and set as a function of the angular position 532, and an electromagnetic holding torque 535 is generated. The electromagnetic holding torque 535 limits at least a movement of the spindle 125 of FIG. 1, FIG. 2, and FIG. 4. Alternatively, the electromagnetic holding torque 535 generates a standstill of the spindle 125 of FIG. 1, FIG. 2, and FIG. 4 at the predefined angular position.

In the second actuation mode, after a determination of the current angular position 532 of the spindle 125 of FIG. 1, FIG. 2, and FIG. 4, a query 533 is carried out as to whether the current angular position 532 corresponds to a predefined angular position. Preferably, the control and regulation unit 195 of FIG. 1 actuates the drive unit 120 of FIG. 1 and FIG. 2 in rotation for setting the predefined angular position of the spindle 125 of FIG. 1, FIG. 2, and FIG. 4 if the current angular position 532 does not correspond to the predefined angular position. Furthermore, the control and regulation unit 195 of FIG. 1 generates, in the second actuation mode, the electromagnetic holding torque 535 for bringing about a standstill of the spindle 125 of FIG. 1, FIG. 2, and FIG. 4 in the predefined angular position. Preferably, a magnetic field assigned to the stator 210 of FIG. 2 generates the electromagnetic holding torque 535.

Other forces against which the electromagnetic holding torque is preferably intended to counteract may be, for example, gravity, in the case of a possible imbalance of a spindle assembly, in particular, during vertical operation, or magnetic or ferromagnetic cogging torques acting on the magnetic disk 280 of FIG. 2 of the rotor 220 of FIG. 2 and FIG. 4.

Preferably, in the second actuation mode, the control and regulation unit 195 actuates the drive unit 120 of FIG. 1 and FIG. 2, or the spindle 125 of FIG. 1, FIG. 2, and FIG. 4, such that complex movement patterns of the spindle 125 of FIG. 1, FIG. 2, and FIG. 4 and/or an oscillating movement in a predefined angular range may occur. Complex movement patterns may, in this case, be arbitrary movement sequences. In the case of such an oscillating movement in a predefined angular range, a frequency for the back-and-forth movement of the spindle 125 of FIG. 1, FIG. 2, and FIG. 4 may preferably be set.

Preferably, a drive voltage 523, 534 is provided per coil 251 of FIG. 2 and FIG. 3. The ratio of the drive voltages 523, 534 relative to one another and their amplitude determine a direction and a magnitude of the second magnetic field assigned to the stator 210 of FIG. 2. The first and second operating modes differ substantially in how the direction of the second magnetic field assigned to the stator 210 of FIG. 2 behaves relative to the direction of the first magnetic field assigned to the rotor 220 of FIG. 2 and FIG. 4, or relative to the angular position of the spindle 125 of Fig. FIG. 1, FIG. 2 and FIG. 4.

What is claimed is:

1. A method for operating a rotating laser, which is operable in at least a first operating mode or a second operating mode and includes a housing, in which, for rotation of a laser beam, a drive unit having a stator and a rotor for rotationally driving a spindle is arranged, wherein a control and regulation unit for actuating the drive unit is assigned to the drive unit, the method comprising:
in response to a selection of the first operating mode, actuating the drive unit by the control and regulation unit with a first actuation mode assigned to the first operating mode, to which a brushless direct-current motor logic is assigned;
in response to a selection of the second operating mode, actuating the drive unit by the control and regulation unit with a second drive-control mode assigned to the second operating mode, to which a stepper-motor logic is assigned, and
driving the drive unit in the first actuation mode, or driving the drive unit in the second actuation mode, wherein the drive unit is drivable in each case with a plurality of drive voltages, which are assigned to the selected operating mode and are ascertained as a function of a current angular position of the spindle.

2. The method according to claim 1, wherein:
the control and regulation unit, in the first actuation mode for generating a rotation, actuates the drive unit such that a magnetic field of the stator leads a magnetic field of the rotor by 90° in a predefined direction of rotation, and
the amplitude of the magnetic field of the rotor is regulated as a function of a rate of change of the current angular position such that the drive unit rotates at a predefined rotational speed.

3. The method according to claim 1, wherein:
in the second actuation mode, after a determination of the current angular position of the spindle, a query is carried out as to whether the current angular position corresponds to a predefined angular position.

4. The method according to claim 3, wherein the control and regulation unit actuates the drive unit for setting the predefined angular position of the spindle if the current angular position does not correspond to the predefined angular position.

5. The method according to claim 3, wherein the control and regulation unit, in the second actuation mode, generates an electromagnetic holding torque for bringing about a standstill of the spindle in the predefined angular position.

6. The method according to claim 5, wherein a magnetic field assigned to the stator generates the electromagnetic holding torque.

7. The method according to claim 1, wherein the control and regulation unit, in the second actuation mode, actuates the drive unit such that complex movement patterns of the spindle and/or an oscillating movement in a predefined angular range are carried out.

8. A rotating laser that is operable in at least a first operating mode or a second operating mode, comprising:
a housing;
a drive unit arranged in the housing and configured to rotate a laser beam, the drive unit having a stator and a rotor configured to rotationally drive a spindle;
a control and regulation unit assigned to the drive unit and configured to actuate the drive unit,
wherein, in the first operating mode, the control and regulation unit actuates the drive unit with a first actuation mode assigned to the first operating mode, to which a brushless direct-current motor logic is assigned, and
wherein, in the second operating mode, the control and regulation unit actuates the drive unit with a second actuation mode assigned to the second operating mode, to which a stepper motor logic is assigned.

9. The rotating laser according to claim 8, wherein the drive unit is drivable in each case with a plurality of drive voltages, which is assigned to the selected operating mode and is determinable as a function of a current angular position of the spindle.

10. The rotating laser according to claim 8, wherein:
the rotor generates a first magnetic field and the stator generates a second magnetic field, and
an alignment of the first and second magnetic field is effected by driving the drive unit with the plurality of drive voltages assigned to the respective operating mode.

11. The rotating laser according to claim 10, wherein:
the rotor includes a toothed disk rotatable with the spindle and having an interior receptacle, and
in the interior receptacle, a magnetic disk configured to generate the first magnetic field is arranged.

12. The rotating laser according to claim 10, wherein the stator includes a rotationally-fixed printed circuit board having at least two coils facing the magnetic disk for generating the second magnetic field.

13. The rotating laser according to claim 12, wherein an angle sensor configured to detect the current angular position of the spindle is assigned to the printed circuit board.

14. The rotating laser according to claim 13, wherein the angle sensor is designed as a photoelectric barrier.
